(19) United States
(12) Patent Application Publication
(10) Pub. No.: US 2026/0198277 A1
(43) Pub. Date: Jul. 9, 2026

(54) METHOD FOR FILLING A VIA WITH A METAL FILM

(71) Applicant: ASM IP Holding B.V., Almere (NL)

(72) Inventor: Paul Ma, Scottsdale, AZ (US)

(21) Appl. No.: 19/440,740

(22) Filed: Jan. 6, 2026

Related U.S. Application Data
(60) Provisional application No. 63/743,335, filed on Jan. 9, 2025.

(51) Int. Cl. H10W 20/00; C23C 16/04; C23C 16/44; C23C 16/455; C23C 16/458; C23C 16/505; C23C 16/56; H01J 37/32; H10P 14/43; H10P 50/26

(52) U.S. Cl. CPC H10W 20/057; C23C 16/045; C23C 16/4408; C23C 16/45536; C23C 16/45544; C23C 16/45553; C23C 16/4583; C23C 16/505; C23C 16/56; H01J 37/32449; H10P 14/432; H10P 50/266; H01J 2237/332

(57) ABSTRACT

A method for depositing a metal film into a feature on a substrate is disclosed. In particular, the method may comprise a low temperature plasma deposition step, a thermal etching step, and a selective filling step. This method allows for deposition of a metal film that has a lower contact resistance at an interface, resulting in a better electrical performance of a semiconductor device.

### CROSS-REFERENCE TO RELATED APPLICATIONS

This application is a nonprovisional of, and claims priority to and the benefit of, U.S. Provisional Patent Application No. 63/743,335 , filed Jan. 9, 2025 and entitled “METHOD FOR FILLING A VIA WITH A METAL FILM,” which is hereby incorporated by reference herein.

### FIELD OF INVENTION

The present disclosure generally relates to processes for manufacturing electronic devices. More particularly, the disclosure relates to filling a via with a metal film. The metal film may comprise niobium, molybdenum, ruthenium, or tungsten, for example.

### BACKGROUND OF THE DISCLOSURE

In the manufacture of semiconductor devices, a substrate may have features defined. The features may require a metal film to be deposited, resulting in a metal-metal interface. However, contaminants, such as carbon, may migrate onto the metal, resulting in a high contact resistance at the metal-metal interface. Such may result in poor electrical properties of a resulting semiconductor device.

As a result, a method for forming a metal film in a via that allows for a lower contact resistance at a metal-metal interface of the semiconductor device is desired.

### SUMMARY OF THE DISCLOSURE

In at least one embodiment of the invention, a method for depositing a semiconductor film in a feature of a substrate is disclosed. The method may include:
providing a substrate with a plurality of features for processing in a reaction chamber;
depositing a metal film onto the substrate by a low temperature plasma deposition process; and thermally etching a portion of the metal film, such that a remaining portion of the metal film is located in a bottom of the plurality of features; and selectively depositing a metal fill layer within the plurality of features, wherein the metal fill layer comprises at least one of: niobium, molybdenum, ruthenium, or tungsten.

In at least one embodiment of the invention, a semiconductor processing system is disclosed. The semiconductor processing system may comprises: a reaction chamber; a substrate holder disposed within the reaction chamber and configured to hold a substrate to be processed; a gas distributor configured to distribute gas across the substrate disposed on the substrate holder; at least one gas source for providing a gas to the substrate on the substrate holder; and an RF source for generating a plasma from the gas. The semiconductor processing system may be configured to perform a process that comprises: providing a substrate with a plurality of features for processing in a reaction chamber; depositing a metal film onto the substrate by a low temperature plasma deposition process; and thermally etching a portion of the metal film, such that a remaining portion of the metal film is located in a bottom of the plurality of features; and selectively depositing a metal fill layer within the plurality of features, wherein the metal fill layer comprises at least one of: niobium, molybdenum, ruthenium, or tungsten.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWING FIGURES

The patent or application file contains at least one drawing executed in color. Copies of this patent or patent application publication with color drawing(s) will be provided by the Office upon request and payment of the necessary fee.

These and other features, aspects, and advantages of the invention disclosed herein are described below with reference to the drawings of certain embodiments, which are intended to illustrate and not to limit the invention.

FIGS. 1A-1C are flow charts illustrating a method in accordance with at least one embodiment of the invention.

FIGS. 2A-2D are cross-sectional views of a semiconductor device in accordance with at least one embodiment of the invention.

FIG. 3A is a cross-sectional view of a semiconductor device in accordance with at least one embodiment of the invention.

FIG. 3B is a top-down view of a semiconductor device in accordance with at least one embodiment of the invention.

FIG. 3C is a cross-sectional view of a semiconductor device in accordance with at least one embodiment of the invention.

FIG. 4 is a cross-sectional view of a semiconductor processing system in accordance with at least one embodiment of the invention.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride, or silicon carbide.

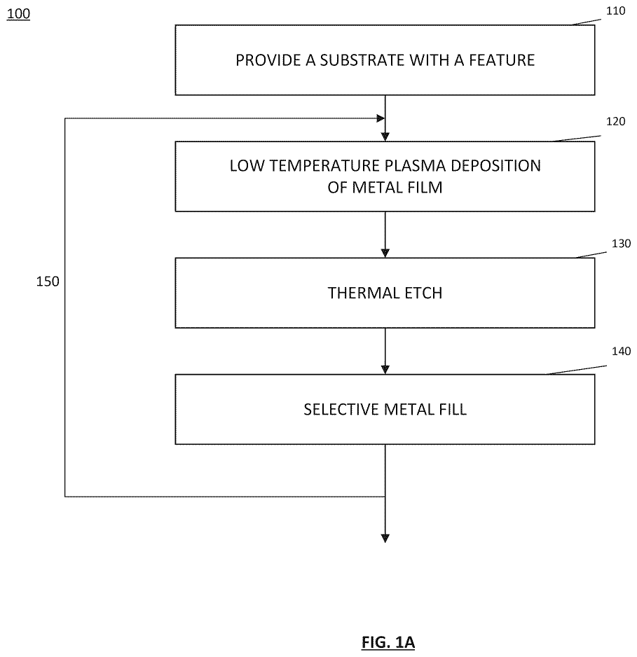

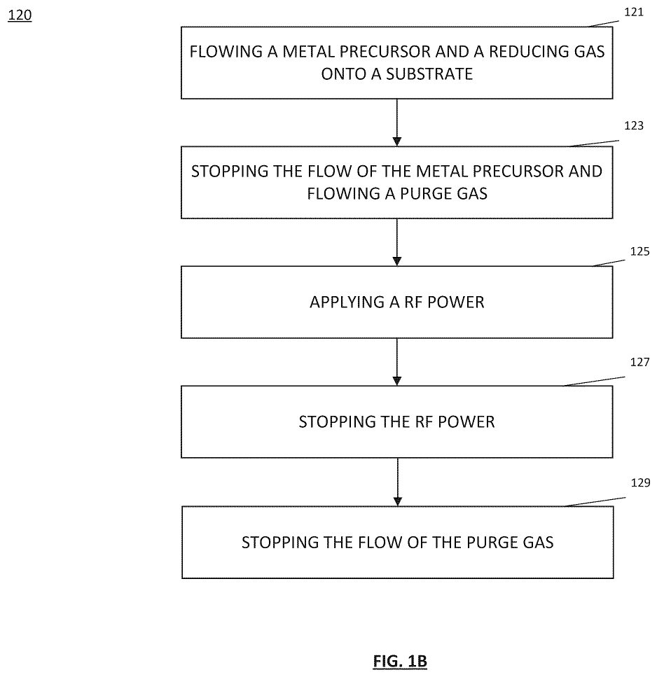

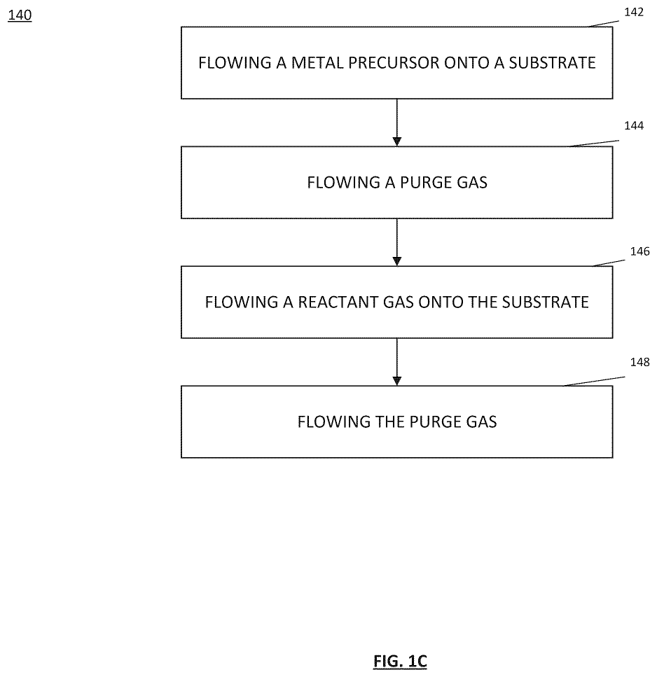

FIG. 1A illustrates a semiconductor deposition process 100 in accordance with at least one embodiment of the invention. The process 100 comprises: (1) a step 110 of providing a substrate with a feature; (2) a step 120 of low temperature plasma deposition of a metal film; (3) a step 130 of a thermal etch; and (4) a step 140 of a selective metal fill. The process may be repeated via a repeat loop 150 in order to achieve a desired fill thickness.

The step 110 comprises placing a substrate having a feature into a semiconductor processing chamber. The semiconductor processing chamber may comprise a single wafer chamber or a multiple wafer chamber, or may be part of a dual chamber module or a quad chamber module. The semiconductor processing chamber may be configured to perform by an atomic layer deposition (ALD), a plasma enhanced atomic layer deposition (PEALD), a chemical vapor deposition (CVD), a plasma enhanced chemical vapor deposition (PECVD), an epitaxial deposition, or a physical vapor deposition (PVD).

The step 120 may take place at a temperature below 400 C, or below 350 C. The step 120 of low temperature plasma deposition of a metal film may comprise multiple sub-steps. The metal film may comprise at least one of: niobium, molybdenum, ruthenium, or tungsten. FIG. 1B illustrates the sub-steps, which may include: (1) flowing a metal precursor and a reducing gas 121; (2) stopping the flow of metal precursor and flowing a purge gas 123; (3) applying a RF power to form a plasma 125; (4) stopping the RF power 127; and (5) stopping the flow of the purge gas 129. The application of the RF power in the sub-step 125 forms the plasma that allows reaction of the metal precursor and the reducing gas to form a metal film onto the substrate.

The metal precursor in the sub-step 121 may comprise at least one of: tungsten tetrafluoride oxide (WOF₄); tungsten tetrachloride oxide (WOCl₄); tungsten dichloride dioxide (WO₂Cl₂); tungsten pentachloride (WCl₅); tungsten hexachloride (WCl₆); tungsten hexafluoride (WF₆); molybdenum tetrafluoride oxide (MoOF₄); molybdenum tetrachloride oxide (MoOCl₄); molybdenum dichloride dioxide (MoO₂Cl₂); molybdenum dibromide dioxide (MoO₂Br₂); molybdenum oxoiodides (MoO₂I or Mo₄O₁₁I); molybdenum pentachloride (MoCl₅); molybdenum hexafluoride (MoF₆); niobium pentachloride (NbCl₅); niobium pentabromide (NbBr₅); (t-butylimido) tris (diethylamino) niobium (((CH₃)₆N)₃NbN(CH₃)₃); allyl ruthenium tricarbonyl (Ru₃(CO)₁₂); or a ruthenium carbonyl complex (Ru(PF₃)₄H₂).

The purge gas may comprise at least one of: nitrogen (N₂), argon (Ar), helium (He), krypton (Kr), other inert gases, or a combination of the above. The reactant gas may be a reducing gas to allow formation of pure metallic film. The reducing gas may comprise at least one of: ammonia (NH₃), hydrogen (H₂), diborane (B₂H₆); silane (SiH₄); germane (GeH₄); monomethylhydrazine (MMH); hydrazine (N₂H₄); or a combination of the above.

The step 130 is a thermal etching step with a metal chloride precursor to partially remove the metal film deposited in the step 120. The metal chloride precursor may comprise at least one of: molybdenum hexafluoride (MoF₆); molybdenum pentachloride (MoCl₅); molybdenum hexabromide (MoBr₆); tungsten hexafluoride (WF₆); fluoride (F₂); carbon tetrafluoride (CF₄); nitrogen trifluoride (NF₃); sulfur hexafluoride (SF₆); chlorine (Cl₂); carbon tetrachloride (CCl₄); or boron trichloride (BCl₃). The step 130 may take place at a temperature of 400 C. The step 130 may be an etch back step to leave a layer or a ring at a bottom of the feature.

The step 140 may be a selective metal fill step that comprises multiple sub-steps to deposit a metal film into the feature. The metal film may comprise at least one of: niobium, molybdenum, ruthenium, or tungsten. FIG. 1C illustrates the sub-steps, which may include: (1) flow a metal precursor 142; (2) flowing a purge gas 144; (3) flowing a reactant gas 146 that reacts with the metal precursor to form the metal film; and (4) flowing a purge gas 148. The selective metal fill step 140 may occur in a way that allows a bottom-up fill of the feature. The selective metal fill step 140 may optionally include using an inhibitor that blocks deposition at an upper portion of the feature.

The metal precursor may comprise at least one of: tungsten tetrafluoride oxide (WOF₄); tungsten tetrachloride oxide (WOCl₄); tungsten dichloride dioxide (WO₂Cl₂); tungsten pentachloride (WCl₅); tungsten hexachloride (WCl₆); tungsten hexafluoride (WF₆); molybdenum tetrafluoride oxide (MoOF₄); molybdenum tetrachloride oxide (MoOCl₄); molybdenum dichloride dioxide (MoO₂Cl₂); molybdenum dibromide dioxide (MoO₂Br₂); molybdenum oxoiodides (MoO₂I or Mo₄O₁₁I); molybdenum pentachloride (MoCl₅); molybdenum hexafluoride (MoF₆); niobium pentachloride (NbCl₅); niobium pentabromide (NbBr₅); (t-butylimido) tris (diethylamino) niobium (((CH₃)₆N)₃NbN(CH₃)₃); allyl ruthenium tricarbonyl (Ru₃(CO)₁₂); or a ruthenium carbonyl complex (Ru(PF₃)₄H₂).

The purge gas in steps 144 and 148 may comprise at least one of: nitrogen (N₂), argon (Ar), helium (He), krypton (Kr), other inert gases, or a combination of the above. The reactant gas in step 146 may be a reducing gas to allow formation of pure metallic film. The reactant gas may comprise at least one of: ammonia (NH₃), hydrogen (H₂), diborane (B₂H₆); silane (SiH₄); germane (GeH₄); monomethylhydrazine (MMH); hydrazine (N₂H₄); or a combination of the above.

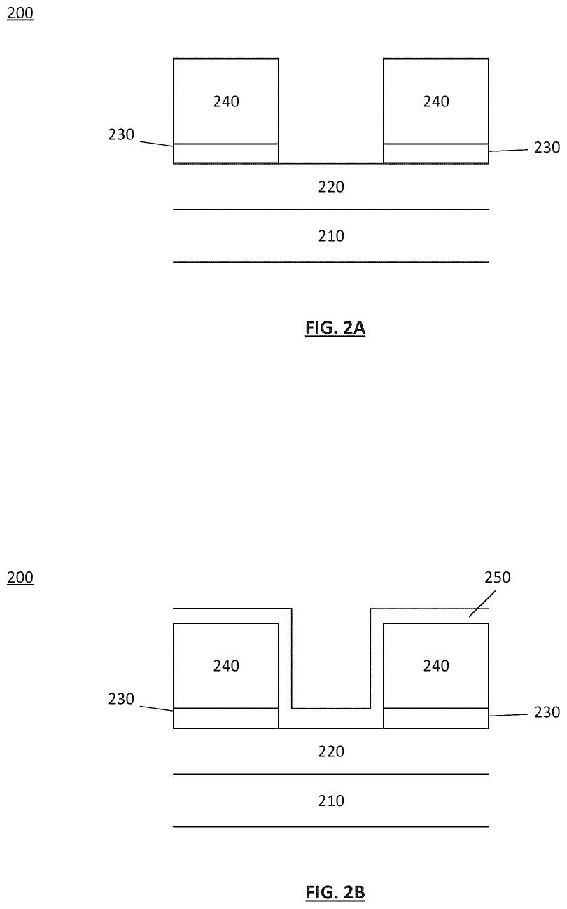

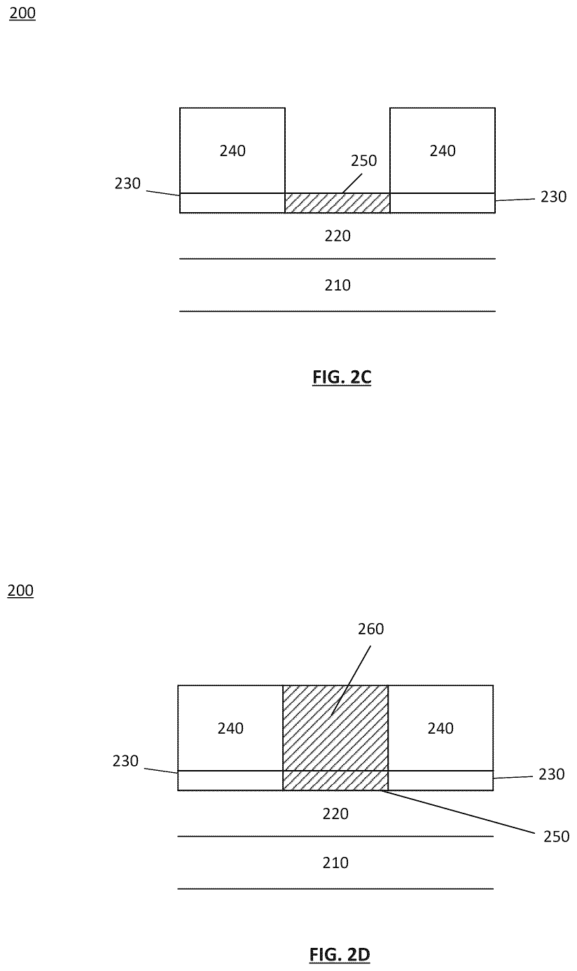

FIG. 2A illustrates a semiconductor device 200 in accordance with at least one embodiment of the invention. The semiconductor device 200 illustrates a substrate that would be provided into a reaction chamber to undergo the metal fill process described earlier. The semiconductor device 200 comprises a wafer 210, a metal layer 220, a low-k layer 230, and a silicon oxide layer 240. The wafer 210 may comprise at least one of:
silicon, silicon germanium, silicon oxide, gallium arsenide, gallium nitride, or silicon carbide.

The metal layer 220 may be deposited onto the wafer 210 and comprise at least one of: niobium, molybdenum, ruthenium, or tungsten. The area above the metal layer 220 between the two low-k layers 230 may be where an additional metal film is deposited, creating a metal-metal interface. The metal layer 220 may be where a contaminant may migrate to, resulting in a depreciated electrical performance.

The low-k layer 230 may be disposed on the metal layer 220 and may comprise at least one of: silicon nitride (SiN), silicon oxycarbide (SiOC), silicon oxycarbonitride (SiOCN), organosilicate glass, or silicon dioxide (SiO₂). The silicon oxide layer 240 may be deposited on the low-k layer.

FIG. 2B illustrates a semiconductor device 200 in accordance with at least one embodiment of the invention. The semiconductor device 200 will have undergone a low temperature PEALD step whereby a metal film 250 is deposited on top of the silicon oxide layer 240 and the metal layer 220. The metal film 250 may comprise at least one of: niobium, molybdenum, ruthenium, or tungsten. Where the metal film 250 and the metal layer 220 meet is the metal-metal interface discussed previously.

FIG. 2C illustrates a semiconductor device 200 in accordance with at least one embodiment of the invention. The semiconductor device 200 will have undergone a thermal etch step whereby portions of the metal film 250 are removed, such that the remaining metal film 250 is disposed on top of the metal layer 220. While the metal film 250 is illustrated as having substantially the same thickness as that of the low-k layer 230, the metal film 250 is not required to be etched to that thickness. The metal film 250 may be thinner or thicker than the low-k layer 230.

FIG. 2D illustrates a semiconductor device 200 in accordance with at least one embodiment of the invention. The semiconductor device 200 will have undergone a selective fill step whereby a metal fill layer 260 is deposited into the feature. Again while the metal fill layer 260 is illustrated as having substantially the same thickness as that of the silicon oxide layer 240, the metal fill layer 260 is not required to be etched to that thickness. The metal fill layer 260 may be thinner or thicker than the silicon oxide layer 240. Most likely being the same material as the metal film 250, the metal fill layer 260 may comprise at least one of: niobium, molybdenum, ruthenium, or tungsten.

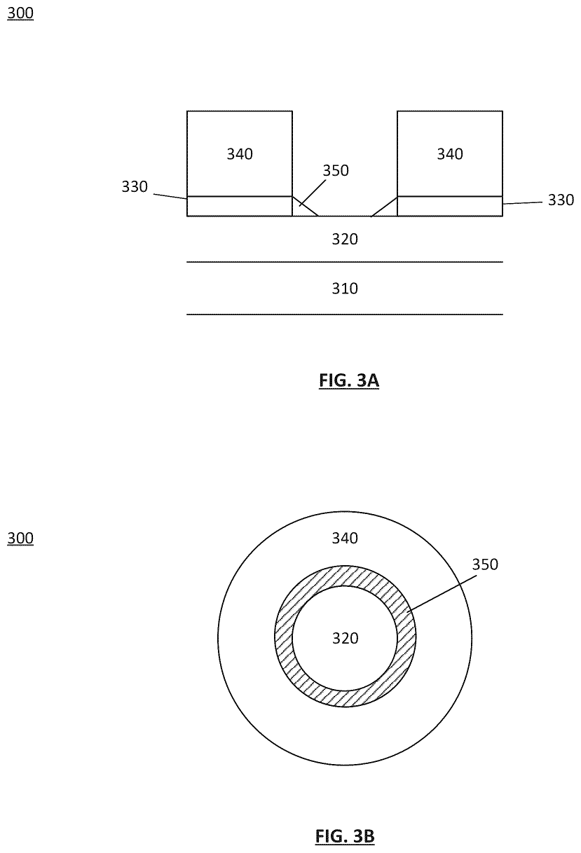

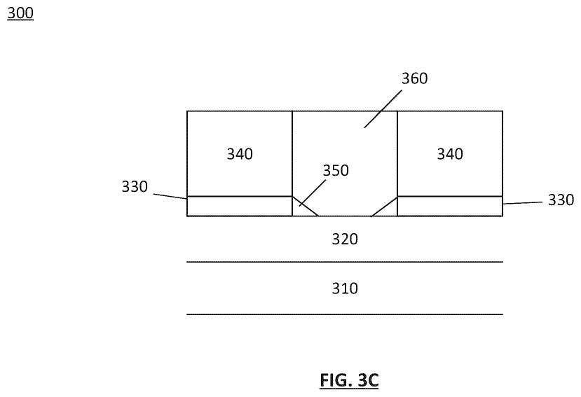

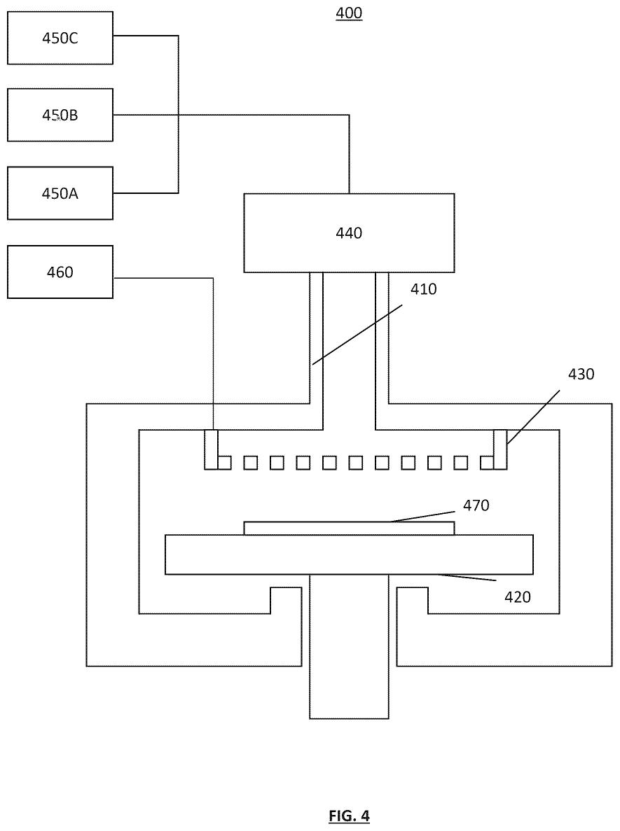

FIG. 3A illustrates a semiconductor device 300 in accordance with at least one embodiment of the invention. The semiconductor device 300 illustrates a substrate that would be provided into a reaction chamber to undergo the metal fill process described earlier. The semiconductor device 300 comprises a wafer 310, a metal layer 320, a low-k layer 330, a silicon oxide layer 340, and a metal ring layer 350. The wafer 310 may comprise at least one of: silicon, silicon germanium, silicon oxide, gallium arsenide, gallium nitride, or silicon carbide.

The metal layer 320 may be deposited onto the wafer 310 and comprise at least one of: niobium, molybdenum, ruthenium, or tungsten. The low-k layer 330 may be disposed on the metal layer 320 and may comprise at least one of: silicon nitride (SiN), silicon oxycarbide (SiOC), silicon oxycarbonitride (SiOCN), organosilicate glass, or silicon dioxide (SiO₂). The silicon oxide layer 340 may be deposited on the low-k layer.

After a thermal etch step takes place in accordance with at least one embodiment of the invention, the thermal etch step may not completely remove the metal layer, resulting in the metal ring layer 350. The metal ring layer 350 may be disposed on the metal layer 320 and comprise at least one of: niobium, molybdenum, ruthenium, or tungsten.

Generally, removal of the metal ring layer 350 may be required such that further processing may result in a desired electrical performance. However, the metal ring layer 350 may provide a benefit in preventing contaminants within the low-k layer 330 or the silicon oxide layer 340 from migrating onto the metal layer 320.

FIG. 3B illustrates the semiconductor device 300 in accordance with at least one embodiment of the invention. Viewed from the top, the semiconductor device 300 comprises the metal layer 320 in the center, followed by the metal ring layer 350 disposed radially from the metal layer 320. The silicon oxide layer 340 then surrounds the metal ring layer 350.

FIG. 3C illustrates a semiconductor device 300 in accordance with at least one embodiment of the invention. The semiconductor device 300 will have undergone a selective fill step whereby a metal fill layer 360 is deposited into the feature. Again while the metal fill layer 360 is illustrated as having substantially the same thickness as that of the silicon oxide layer 340, the metal fill layer 360 is not required to be etched to that thickness. The metal fill layer 360 may be thinner or thicker than the silicon oxide layer 340. Most likely being the same material as the metal ring layer 350, the metal fill layer 360 may comprise at least one of: niobium, molybdenum, ruthenium, or tungsten.

FIG. 4 illustrates a semiconductor processing system 400 in accordance with at least one embodiment of the invention. The semiconductor processing system 400 may comprise: a reaction chamber 410; a substrate holder 420 within the reaction chamber 410; a gas distributor 430; a gas manifold 440; a first gas source 450A; a second gas source 450B, a third gas source 450C, and a RF power source 460. The substrate holder 420 may be configured to hold a substrate 470 that undergoes a deposition process as described above.

The gas distributor 430 is used to distribute a metal precursor gas, a reducing gas, a reaction gas, or a purge gas across the substrate 470. The gas manifold 440 may be configured to receive a gas from the first gas source 450A, the second gas source 450B, and the third gas source 450C. While three gas sources are illustrated in FIG. 4, there may be more or less gas sources in the semiconductor processing system 400. The RF power source 460 may provide an RF power to the gas distributor 430 or other part of the semiconductor processing system 400 to form a plasma with the gases in the reaction chamber 410. The gases then may react to form a metal layer or a metal fill layer as previously disclosed.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

We claim:

1. A method of forming a semiconductor film on a substrate comprising:
providing a substrate with a plurality of features for processing in a reaction chamber;
depositing a metal film onto the substrate by a low temperature plasma deposition process; and
thermally etching a portion of the metal film, such that a remaining portion of the metal film is located in a bottom of the plurality of features; and
selectively depositing a metal fill layer within the plurality of features, wherein the metal fill layer comprises at least one of: niobium, molybdenum, ruthenium, or tungsten.

2. The method of claim 1, wherein the low temperature plasma deposition process comprises:
flowing a metal precursor and a reducing gas onto the substrate;
stopping the flow of the metal precursor and flowing a purge gas;
applying a RF power to generate a plasma that forms the metal film on the substrate;
stopping the RF power; and
stopping the flow of the purge gas.

3. The method of claim 2, wherein the metal precursor comprises at least one of: tungsten tetrafluoride oxide (WOF₄); tungsten tetrachloride oxide (WOCl₄); tungsten dichloride dioxide (WO₂Cl₂); tungsten pentachloride (WCl₅); tungsten hexachloride (WCl₆); tungsten hexafluoride (WF₆); molybdenum tetrafluoride oxide (MoOF₄); molybdenum tetrachloride oxide (MoOCl₄); molybdenum dichloride dioxide (MoO₂Cl₂); molybdenum dibromide dioxide (MoO₂Br₂); molybdenum oxoiodides (MoO₂I or Mo₄O₁₁I); molybdenum pentachloride (MoCl₅); molybdenum hexafluoride (MoF₆); niobium pentachloride (NbCl₅); niobium pentabromide (NbBr₅); (t-butylimido) tris (diethylamino) niobium (((CH₃)₆N)₃NbN(CH₃)₃); allyl ruthenium tricarbonyl (Ru₃(CO)₁₂); or a ruthenium carbonyl complex (Ru(PF₃)₄H₂).

4. The method of claim 2, wherein the reducing gas comprises at least one of: hydrogen (H₂); diborane (B₂H₆); silane (SiH₄); germane (GeH₄); ammonia (NH₃); monomethylhydrazine (MMH); or hydrazine (N₂H₄).

5. The method of claim 2, wherein the purge gas comprises at least one of: argon (Ar); hydrogen (H₂); nitrogen (N₂); or krypton (Kr).

6. The method of claim 1, wherein the thermally etching the metal film further comprises:
flowing an etch gas; and
purging the etch gas from the reaction chamber with a purge gas.

7. The method of claim 6, wherein the etch gas comprises at least one of: molybdenum hexafluoride (MoF₆); molybdenum pentachloride (MoCl₅); molybdenum hexabromide (MoBr₆); tungsten hexafluoride (WF₆); fluoride (F₂); carbon tetrafluoride (CF₄); nitrogen trifluoride (NF₃); sulfur hexafluoride (SF₆); chlorine (Cl₂); carbon tetrachloride (CCl₄); or boron trichloride (BCl₃).

8. The method of claim 6, wherein the purge gas comprises at least one of: argon (Ar); hydrogen (H₂); nitrogen (N₂); or krypton (Kr).

9. The method of claim 1, wherein the selectively depositing the metal fill layer further comprises:
flowing a metal precursor onto the substrate;
purging the metal precursor from the reaction chamber with a purge gas;
flowing a reactant gas onto the substrate, wherein the reactant gas reacts with the metal precursor to form the metal fill layer; and
purging the reactant gas from the reaction chamber with the purge gas.

10. The method of claim 9, wherein the metal precursor comprises at least one of: tungsten tetrafluoride oxide (WOF₄); tungsten tetrachloride oxide (WOCl₄); tungsten dichloride dioxide (WO₂Cl₂); tungsten pentachloride (WCl₅); tungsten hexachloride (WCl₆); tungsten hexafluoride (WF₆); molybdenum tetrafluoride oxide (MoOF₄); molybdenum tetrachloride oxide (MoOCl₄); molybdenum dichloride dioxide (MoO₂Cl₂); molybdenum dibromide dioxide (MoO₂Br₂); molybdenum oxoiodides (MoO₂I or Mo₄O₁₁I); molybdenum pentachloride (MoCl₅); molybdenum hexafluoride (MoF₆); niobium pentachloride (NbCl₅); niobium pentabromide (NbBr₅); (t-butylimido) tris (diethylamino) niobium (((CH₃)₆N)₃NbN(CH₃)₃); allyl ruthenium tricarbonyl (Ru₃(CO)₁₂); or a ruthenium carbonyl complex (Ru(PF₃)₄H₂).

11. The method of claim 9, wherein the reactant gas comprises at least one of: hydrogen (H₂); diborane (B₂H₆); silane (SiH₄); germane (GeH₄); ammonia (NH₃); monomethylhydrazine (MMH); or hydrazine (N₂H₄).

12. The method of claim 9, wherein the purge gas comprises at least one of: argon (Ar); hydrogen (H₂); nitrogen (N₂); or krypton (Kr).

13. The method of claim 1, wherein the depositing the metal film takes place at a temperature ranging between 200 and 400 C.

14. The method of claim 1, wherein the selectively depositing the metal fill layer takes place at a temperature greater than a temperature during the depositing the metal film.

15. The method of claim 14, wherein the temperature during the selectively depositing the metal fill layer is greater than 400 C.

16. A semiconductor processing system for forming a semiconductor film on a substrate comprising:
a reaction chamber;
a substrate holder disposed within the reaction chamber and configured to hold a substrate to be processed;
a gas distributor configured to distribute gas across the substrate disposed on the substrate holder;
at least one gas source for providing a gas to the substrate on the substrate holder; and
an RF source for generating a plasma from the gas;
wherein the semiconductor processing system is configured to perform a method comprising:
providing a substrate with a plurality of features for processing in a reaction chamber;
depositing a metal film onto the substrate by a low temperature plasma deposition process; and
thermally etching a portion of the metal film, such that a remaining portion of the metal film is located in a bottom of the plurality of features; and
selectively depositing a metal fill layer within the plurality of features, wherein the metal fill layer comprises at least one of: niobium, molybdenum, ruthenium, or tungsten.
